(19) United States
(12) Patent Application Publication
(10) Pub. No.: US 2009/0014807 A1
(43) Pub. Date: Jan. 15, 2009

(54) DUAL STRESS LINERS FOR INTEGRATED CIRCUITS

(75) Inventors: Teck Jung TANG, Johor Bahru (MY); Dae Kwon Kang, Suwon-Si (KR); Sunfei Fang, New York, NY (US); Tae Hoon Lee, Suwon-Si (KR); Scott D. Allen, Ledgewood, NJ (US); Fang Chen, Singapore (SG); Frank Huebinger, Poughkeepsie, NY (US); Jun Jung Kim, Paju-Si (KR); Jae Eun Park, Fishkill, NY (US)

Correspondence Address: HORIZON IP PTE LTD, 7500A Beach Road, #04-306/308 The Plaza, SINGAPORE 199591, SG

(73) Assignees: Chartered Semiconductor Manufacturing, Ltd., Singapore (SG); Samsung Electronics Co., Ltd, Suwon-Si (KR); International Business Machines Corporation, New York (US); Infineon Technologies AG, Munich (DE)

(21) Appl. No.: 11/777,290

(22) Filed: Jul. 13, 2007

(51) Int. Cl. H01L 29/94; H01L 21/8238

(52) U.S. Cl. 257/369; 438/218; 438/229; 257/E29.345; 257/E21.632

(57) ABSTRACT

Dual stress liners for CMOS applications are provided. The dual stress liners can be formed from silicon nitride having a first portion for inducing a first stress and a second portion for inducing a second stress. An interface between the first and second stress portions is self-aligned and co-planar. To produce a co-planar self-aligned interface, polishing, for example, mechanical chemical polishing is used.

### FIELD OF THE INVENTION

The present invention relates generally to integrated circuits, and more particularly to dual stress liners for complementary metal oxide semiconductor (CMOS) applications.

### BACKGROUND OF THE INVENTION

Integrated circuits (ICs) typically comprise numerous circuits components interconnected to perform the desired functions. Field effect transistors (FETs) exhibit hot carrier effect caused by high electric fields at the end of the channel near the source drain diffusion regions. Carriers are accelerated by the high electric field. When the carriers achieve sufficient energy, electron hole pairs are generated by impact ionization. The electrons and holes can penetrate the gate oxide and become trapped therein. As the trapped charge accumulates, transistor parameters, performance as well as reliability can be negatively impacted. For example, hot carrier effect can cause shifts in gate threshold voltage, high leakage current or gate oxide breakdown.

Strain generation in silicon has been proposed to improve carrier mobility which decreases trapped charges in the gate oxide. Stress inducing liners are used to induce stress. However, hot electrons are more mobile than hot holes. To compensate for the differences in mobility, different stresses are applied to the pFETs and nFETs. Dual stress inducing liners can be used to induce different stresses in respective pFETs and nFETs. For example, a compressive stress inducing nitride liner is provided over the pFETs while a tensile stress inducing nitride liner is provided over the nFETs.

Typically, one liner overlaps the other liner to ensure that no gaps exist between the two liners. At the region where the liners overlap, the thickness is about double that of the non-overlapping regions. The non-uniformity in thickness between the overlap and non-overlap regions creates problems in subsequent processes, which can lead to decreased reliability.

From the foregoing discussion, it is desirable to provide improved dual liners which increase reliability as well as performance of ICs.

### SUMMARY OF THE INVENTION

The present invention relates generally to ICs. In particular, the present invention relates to improving performance of ICs with stress inducing liners to enhance charge carrier mobility. In one aspect of the invention, an IC is provided. The IC comprises first and second active regions defined on a substrate with first and second transistors, wherein the first transistor comprises a first type and the second transistor comprises a second type. A first stress layer covers the first transistor. The first stress layer creates a first stress. Covering the second transistor is a second stress layer which creates a second stress. The interface between the first and second stress layers is located between the first and second active regions. The region between the first and second active regions, for example, comprises an isolation region, such as shallow trench isolation. The interface is self-aligned and comprises a substantially polished planar surface.

In another aspect of the invention, a method of fabricating an integrated circuit is provided. The method comprises providing a substrate with first and second active regions defined thereon with first and second transistors. The first transistor comprises a first transistor type and the second transistor comprises a second transistor type, and a region between the first and second active regions. The region between the first and second regions, in one embodiment, comprises an isolation region. A first stress layer is formed on the substrate to cover the first transistor. The first stress layer produces a first stress. A second stress layer is formed on the substrate and produces a second stress. The second stress layer overlaps the first stress layer in the isolation region. The portion of the stress layer which overlaps the first stress layer is removed by polishing, producing an interface between the first and second stress layers having a coplanar upper surface without a gap.

In yet another aspect of the invention, a method of fabricating an integrated circuit is provided. The method comprises providing a substrate with first and second active regions defined thereon with first and second transistors. The first transistor comprises a first type and the second transistor comprises a second type, and a region between the first and second active regions. The region between the active regions, for example, comprises an isolation region. A first stress layer is formed on the substrate, covering the first and second transistors. The first stress layer produces a first stress. The first stress layer is patterned to remove portions of the first stress layer over the second active region. A second stress layer is formed on the substrate, wherein the second stress layer produces a second stress. Portions of the second stress layer over the first active region is removed, leaving an overlap of the second stress layer over the first stress layer in the region between the active regions to avoid gaps between the first and second stress layers. A polishing step is performed to produce an interface between the first and second stress layers having a coplanar upper surface without a gap.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Various embodiments of the present invention are described with reference to the following drawings, in which:

FIG. 1 shows a cross-section of portion of an IC in accordance with one embodiment of the invention; and

FIGS. 2a-j illustrate a process flow for forming an IC in accordance with one embodiment of the invention.

### DETAILED DESCRIPTION OF THE INVENTION

The present invention relates to ICs. More particularly, the present invention relates to dual stress liners which improve reliability and performance without incurring area penalties or layout inefficiencies. The invention can be applied to various types of ICs, such as memory devices including dynamic random access memories (DRAMs), static random access memories (SRAMs), non-volatile memories including programmable read-only memories (PROM) and flash memories, optoelectronic devices, logic devices, communication devices, digital signal processors (DSPs), microcontrollers, system-on-chip, as well as other types of devices.

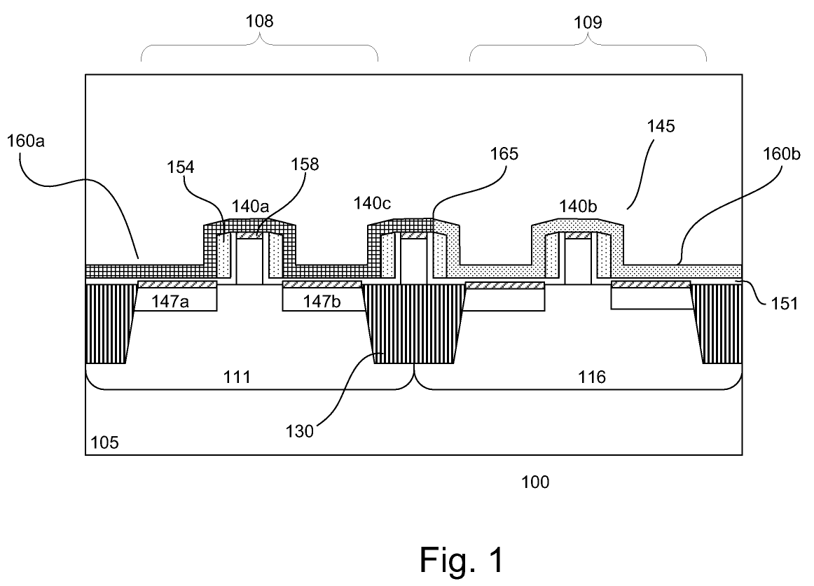

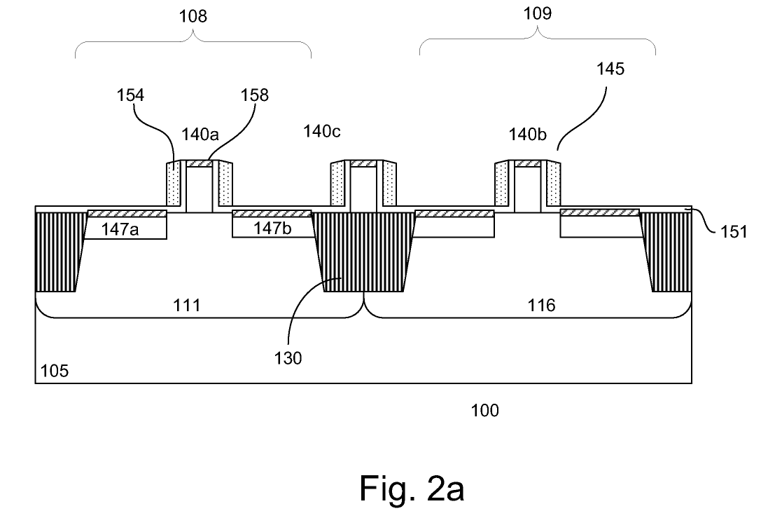

FIG. 1 shows a cross-sectional view of a portion of an IC 100 in accordance with one embodiment of the invention. The IC comprises a substrate 105. Defined on the substrate are first and second active regions 108 and 109. The first active region includes a first doped well 111 of a first charge carrier type; the second active region includes a second doped well 116 having a second charge carrier type. In one embodiment, a region 130 is provided between the active regions. The region, for example comprises an isolation region. Isolation regions can also be provided to separate the active regions from other regions. In one embodiment, the isolation regions comprise shallow trench isolation (STI) regions. STIs comprise trenches formed in the substrate and filled with dielectric material, such as silicon oxide. Other types of isolation regions are also useful.

First and second transistors 140a-b are provided in the first and second active regions. A transistor includes a gate stack 145 and source/drain diffusion regions 147a-b. The gate stack generally comprises polysilicon over a gate oxide. Dielectric liner 151 and spacers 154 can be provided. The liner lines the gate and substrate while the spacers are disposed on the gate sidewalls. Typically the liner comprises oxide while the spacers are formed from nitride. Other combinations of materials are also useful. Alternatively, only a dielectric liner is provided. Silicide contacts 158 can be provided on the top of the gate and diffusion regions to reduce sheet resistance. The contacts serve as terminals of the transistors.

In one embodiment, the first transistor comprises a n-type transistor (nFET) and is provided in the first active region and the second transistor comprises a p-type transistor (pFET) and is formed in the second active region. The charge carrier of the pFET comprises holes and the charge carrier of the nFET comprises electrons. This produces a configuration having a nFET in a p-well and a pFET in a n-well.

To improve carrier mobility, strain is induced in the silicon. The strain can be induced by providing a stress layer over the transistors. Different types of charge carriers react differently to different types of stresses. First and second stress layers 160a-b are provided over respective first and second transistors to improve mobility charge carriers. In one embodiment, the first stress layer comprises a tensile stress inducing material and the second stress material comprises a compressive stress inducing layer. The first and second stress inducing materials, in one embodiment, comprise silicon nitride. Other types of stress inducing materials are also useful.

An interface 165 of the first and second stress layers is located in the area between the first and second active regions. The interface is located above the isolation region between the first and second active regions. In one embodiment, the interface is disposed on a feature 140c over the isolation region. The height of the feature, in one embodiment, is equal to or greater than the gates of the transistor. The feature, for example, comprises a gate. Other types of features are also useful. Providing a feature over the isolation region enables the overlap region of the stress layers to be elevated. Other techniques for elevating the overlap region are also useful.

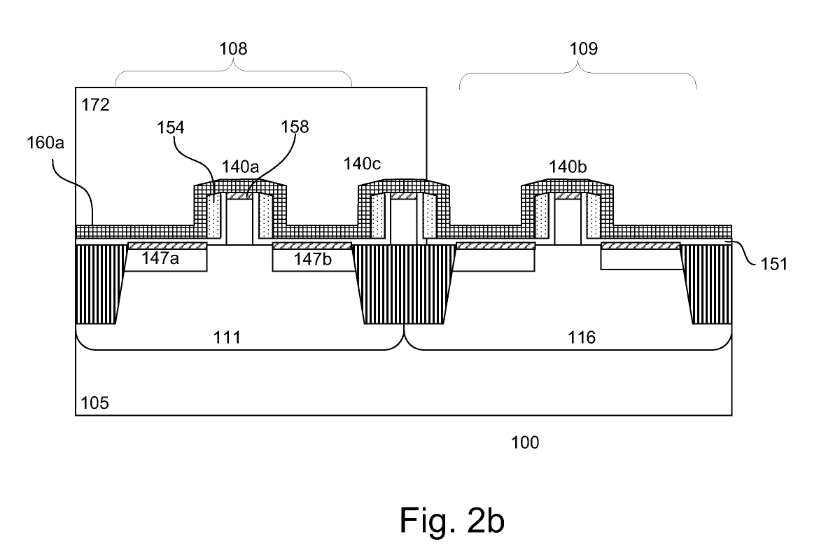

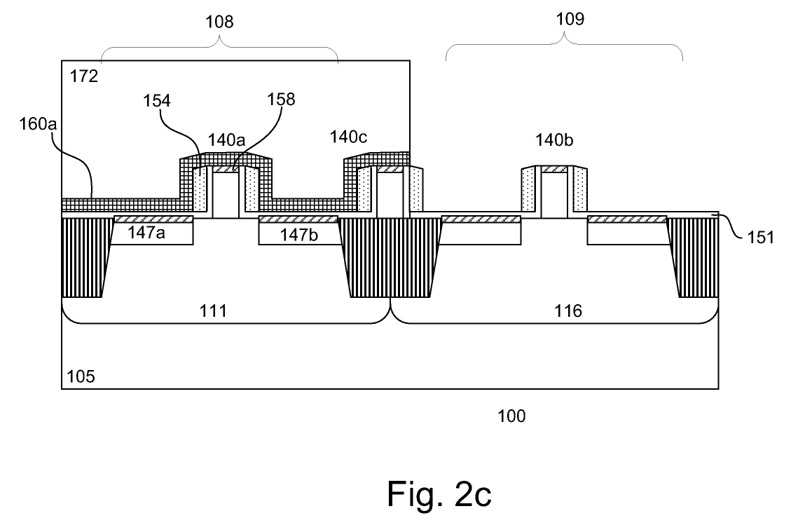

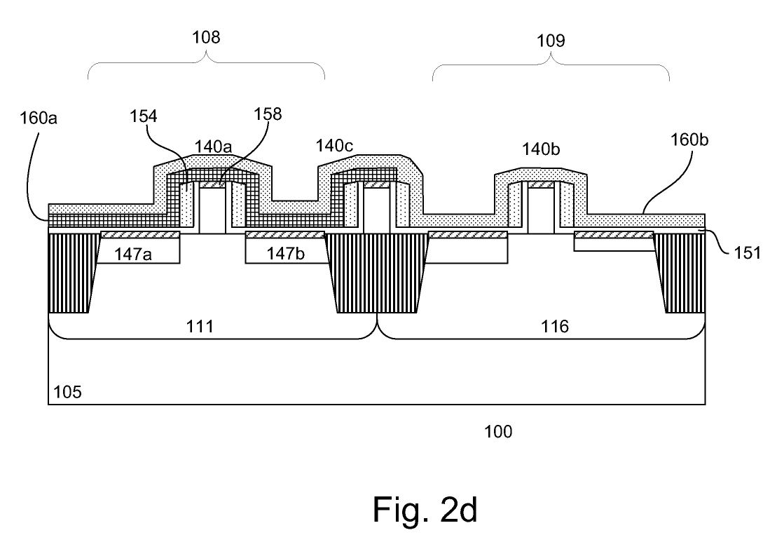

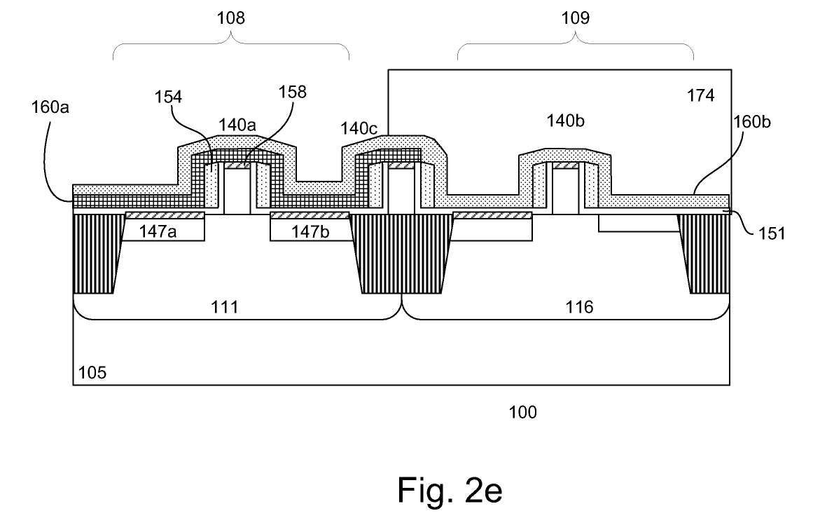

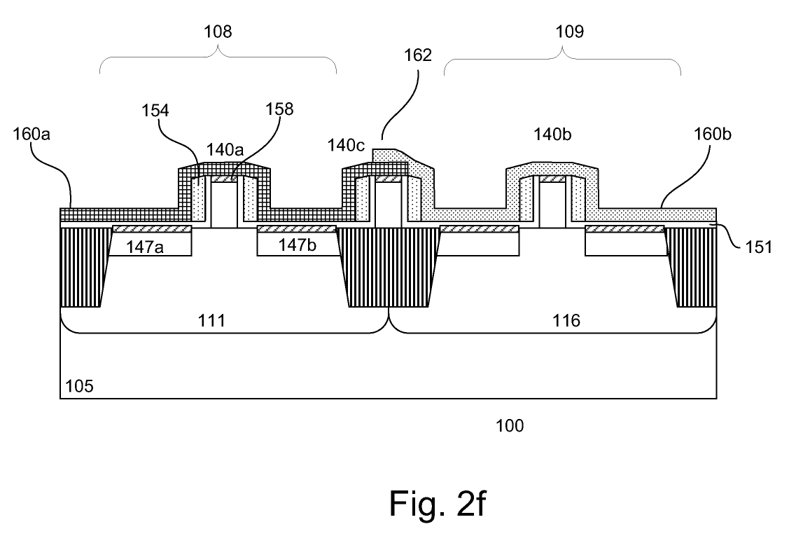

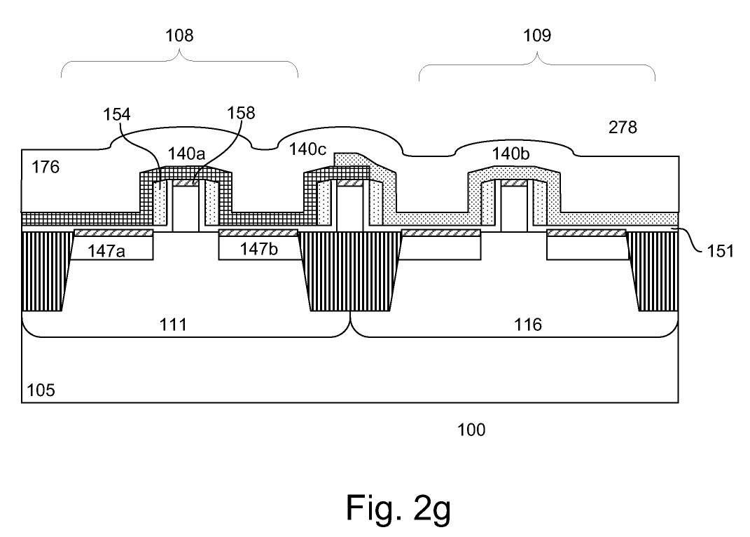

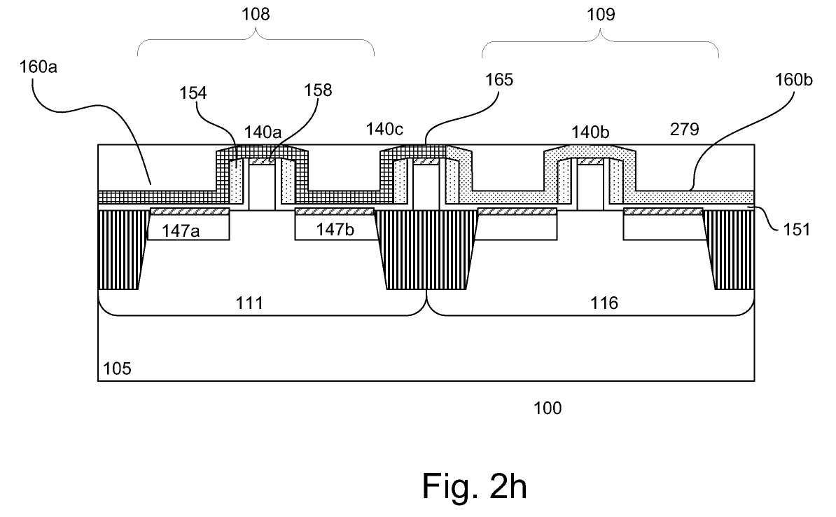

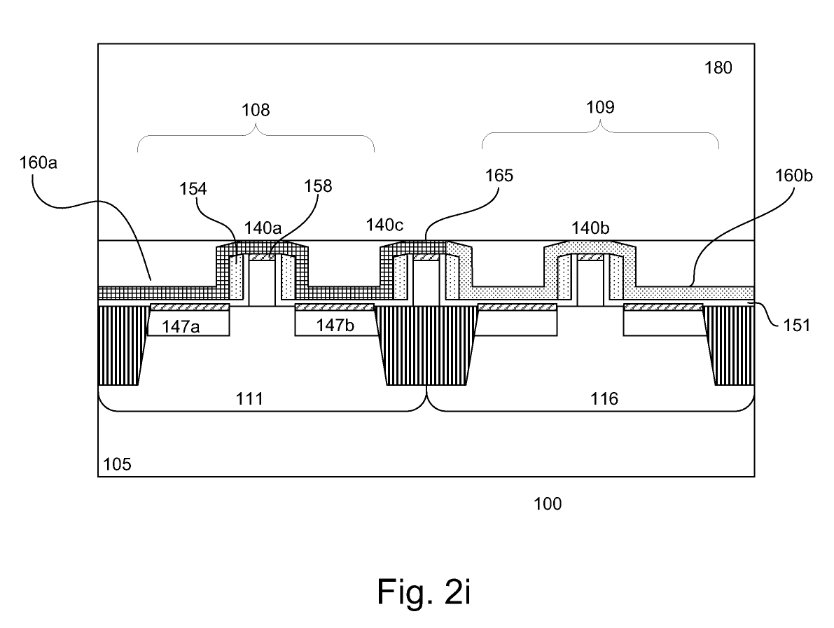

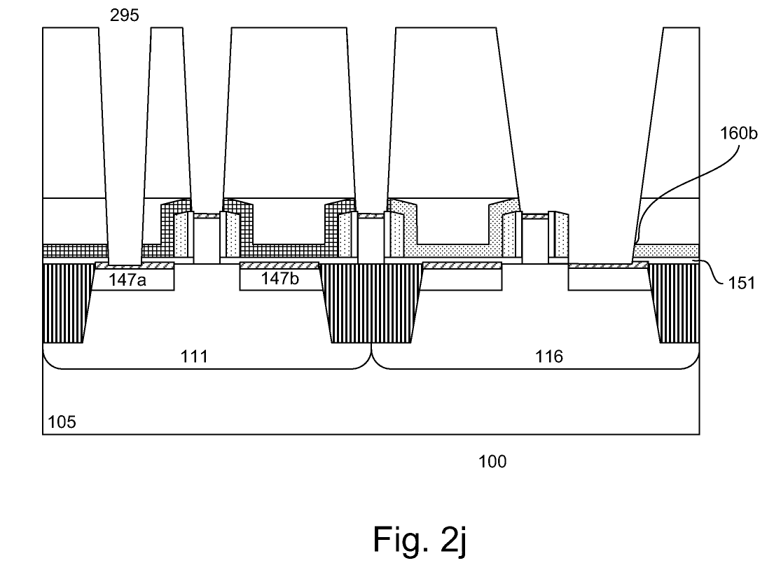

FIGS. 2a-j illustrate an exemplary process flow for forming an IC in accordance with one embodiment of the invention. Referring to FIG. 2a, a substrate 100 is provided. The substrate comprises a semiconductor substrate 105, such as silicon. Other types of semiconductor substrates, for example, SiGe, SiGeC, SiC, silicon-on-insulators (SOIs), SiGe-on-insulators (SGOIs), are also useful. In one embodiment, the substrate comprises a lightly doped p-type substrate. The substrate is prepared with first and second active regions, 108 and 109, with first and second doped wells 111 and 116. The first doped well, for example, is a p-well and the second doped well is a n-well.

In one embodiment, a nFET is formed in the p-well and a pFET is formed in the n-well. A FET includes a gate stack 145 and source/drain diffusion regions 147a-b. The pFET comprises p-type diffusion regions and the nFET comprises n-type diffusion regions. The gate stack generally comprises polysilicon over a gate oxide. Dielectric liner 151 and spacers 154 are provided on the gate sidewalls. Typically the liner comprises oxide while the spacers are formed from nitride. Silicide contacts 158 can be provided on the top of the gate and diffusion regions. Isolation regions 130, such as STI regions, are provided to isolate the first and second active regions from each other as well as from other active regions. In one embodiment, the substrate is prepared with a feature 140c, for example, a gate stack, in the isolation region between the first and second active regions. The various features such as doped wells, STIs, transistors, spacers and liners are formed using conventional processes.

Referring to FIG. 2b, a first stress layer 160a is deposited on the surface of the substrate. In one embodiment, the first stress layer comprises a first stress inducing material. The first stress inducing material enhances charge carrier mobility of the first transistor 140a. In one embodiment, the first stress inducing material comprises a tensile stress inducing material. The stress inducing material comprises, in one embodiment, silicon nitride. The thickness of the tensile stress layer, for example, is about 400-1000 Å and preferably about 500 Å. Other thicknesses may also be useful. Various techniques can be used to form the tensile stress layer. For example, the first stress layer can be formed using chemical deposition techniques, such as low pressure CVD (LPCVD), plasma enhanced CVD (PECVD), rapid thermal CVD (RTCVD) or BTBAS-based CVD. The tensile stress layer, in accordance with one embodiment of the invention, is deposited by PECVD using a SiH₄ precursor.

A photoresist layer 172 is deposited on the substrate, covering the first stress layer. The photoresist layer is patterned to expose portions of the first stress layer covering the second transistor 140b in the second active region. In one embodiment, the photoresist layer is patterned to expose the tensile stress layer over the pFET in the second active region. Conventional techniques, such as exposure and development, are used to pattern the photoresist layer. An antireflective coating can be provided beneath the photoresist layer. The exposed portions of the first stress layer are removed, as shown in FIG. 2c. Removal can be achieved using, for example, an anisotropic etch such as reactive ion etch (RIE). The etch preferably is selective to the liner layer. After patterning the first stress layer, the photoresist is removed.

Referring to FIG. 2d, a second stress layer 160b is deposited on the substrate. The second stress layer covers the second transistor in the second active region and first stress layer over the first active region. The second stress layer comprises a material which enhances charge carrier mobility of the second transistor. In one embodiment, the second stress layer comprises compressive stress material. The compressive stress material, for example, comprises silicon nitride. Typically, the thickness of the second stress layer is about 400-1000 Å. Preferably, the thickness of the second stress layer is about 600 Å. Other thicknesses are also useful. Various techniques, such as low pressure CVD (LPCVD), plasma enhanced CVD (PECVD), high density plasma CVD (HDPCVD), rapid thermal CVD (RTCVD) or BTBAS-based CVD can be used to form the second stress layer. In one embodiment, the second stress layer is formed by HDPCVD using a silane (SiH₄) precursor.

In one embodiment, the first and second stress layers may have different thicknesses to fulfill, for example, different stress requirements of the pFETs and nFETs. It may also be useful to provide stress layers with the same thickness.

As shown in FIG. 2e, a photoresist layer 174 is deposited over the substrate. The photoresist layer is patterned to expose portions of the second stress layer covering the other transistor covered by the first stress layer. In one embodiment, the photoresist layer is patterned to expose the compressive stress layer over the nFET in the first active region. Conventional techniques, such as exposure and development, are used to pattern the resist layer. An antireflective coating can be provided beneath the photoresist layer. The portion of the resist layer remaining should overlap the first stress layer. The amount of the overlap should be sufficient to ensure that no gap is created between the first and second stress layers when portions of the second stress layer unprotected by the resist layer are removed.

The exposed portions of the second stress layer are removed, as shown in FIG. 2f. Removal can be achieved using, for example, an anisotropic etch such as reactive ion etch (RIE). The etch preferably is selective to oxide. After patterning the second stress layer, the resist is removed. The resulting structure includes the first stress layer covering the first active region and the second stress layer covering the second active region. A portion 162 of the second stress layer overlaps and covers the first stress layer in the overlap region. As a result, the thickness of the stress layer in the overlap region is about twice of that in the non-overlap region.

Referring to FIG. 2g, a dielectric layer 176 is deposited on the substrate. The dielectric layer, for example, comprises silicon oxide. Other types of dielectric materials are also useful. Various conventional techniques, such as CVD, can be used to deposit the dielectric layer. The dielectric layer sufficiently covers the substrate. Preferably, the thickness of the dielectric layer should be sufficient to perform the subsequent polishing step. In one embodiment, the height of the dielectric layer at the lowest point should be at least above the stress layers at the overlap region.

Typically, the surface 278 of the oxide layer is uneven due to underlying topography. In accordance with one embodiment of the invention, the dielectric layer is polished. The dielectric layer, in accordance with one embodiment of the invention, is polished by chemical mechanical polish (CMP). The stress layer can serve as a polish stop for the CMP. As shown in FIG. 2h, excess oxide material is removed by the CMP to produce a planar top surface 279. The CMP also removes portions of the second stress layer above the first stress layer in the overlap region. The resulting interface 165 between the dual stress layers is advantageously self-aligned and coplanar.

The process continues for forming the IC. Various types of processes can be performed, depending on the type of IC. Such processes can include, for example, forming interconnects for coupling the transistors as desired. The process of forming interconnects includes forming a dielectric layer 180 over the substrate, as shown in FIG. 2i. The dielectric layer serves as an interlevel dielectric (ILD) layer. Various types of dielectric materials can be used. For example, the dielectric layer can comprise doped silicon oxide such as fluorinated silicon oxide (FSG), undoped or doped silicate glasses such as boron phosphate silicate glass (BPSG) and phosphate silicate glass (PSG), undoped or doped thermally grown silicon oxide, undoped or doped TEOS deposited silicon oxide, as well as low-k or ultra low-k dielectric materials. The dielectric layer can be deposited by, for example, CVD. Other types of dielectric materials or deposition processes can also be used. The thickness of the dielectric layer, for example, is about 2500 Å thick. Other thicknesses are also useful, depending on the application such as subsequent processes.

Referring to FIG. 2j, the dielectric layer is patterned to form contacts and metal lines. Conventional techniques can be used to form contacts and metal lines. For example, conventional dual damascene techniques are used to form contacts and metal lines. Such techniques can include patterning vias 295 in the dielectric layer. The vias provide electrical contact to contact regions below, such as diffusion regions and gates of the transistors. Subsequently, trenches (not shown) can be formed in the upper portion of the dielectric layer for metal lines. Other processes are also performed to complete the IC. Such processes include, for example, additional metal layers or interconnects, passivation, dicing, assembly and packaging.

In accordance with the invention, dual stress liners can be produced having a self-aligned interface with a polished coplanar upper surface between the different stress materials. The resulting dual stress liners thus have a uniform thickness. This increases the process window for forming contacts.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. An integrated circuit (IC) comprising:
first and second active regions defined on a substrate with first and second transistors, wherein the first transistor comprises a first type and the second transistor comprises a second type;
a first stress layer covering the first transistor, the first stress layer creating a first stress;
a second stress layer covering the second transistor, the second stress layer creating a second stress; and
wherein an interface between the first and second stress layers located between first and second active regions is self-aligned and comprises a substantially polished planar surface.

2. The IC of claim 1 further comprising a shallow trench isolation region separating the first and second active regions.

3. The IC of claim 2 wherein a third transistor gate is provided on a surface of the isolation region.

4. The IC of claim 1 comprises a feature on an isolation region separating the first and second active regions, the feature comprises a height equal to or greater than a height of gates of the transistors.

5. The IC of claim 4 wherein the isolation region comprises a shallow trench isolation region.

6. The IC of claim 1 wherein a third transistor gate is provided on a surface of an isolation region separating the first and second active regions.

7. The IC of claim 1 wherein:
the first transistor is a nFET;
the second transistor is a pFET;
the first stress comprising a tensile stress; and
the second stress comprising a compressive stress.

8. The IC of claim 7 wherein the first stress layer comprises silicon nitride creating the first stress and the second stress layer comprises silicon nitride creating the second stress.

9. The IC of claim 8 further comprising a contact at the interface of the first and second stress layers.

10. The IC of claim 7 further comprising a contact at the interface of the first and second stress layers.

11. The IC of claim 1 wherein the first stress layer comprises silicon nitride creating the first stress and the second stress layer comprises silicon nitride creating the second stress.

12. The IC of claim 1 further comprising a contact at the interface of the first and second stress layers.

13. A method of fabricating an integrated circuit comprising:
providing a substrate with first and second active regions defined thereon with first and second transistors, the first transistor comprises a first type and the second transistor comprises a second type, and an isolation region between the first and second active regions;
forming a first stress layer on the substrate to cover the first transistor, the first stress layer produces a first stress for enhancing mobility of a second charge carrier type;
forming a second stress layer on the substrate, the second stress layer produces a second stress to enhance mobility of a first charge carrier type, wherein the second stress layer overlaps the first stress layer in the isolation region; and
polishing the substrate to remove a portion of the second stress layer that overlaps the first stress layer to produce an interface between the first and second stress layers having a coplanar upper surface without a gap.

14. The method of claim 13 further comprises providing a third gate on the isolation region, wherein the interface between the first and second stress layers is disposed on the third gate.

15. The method of claim 13 further comprises providing a feature on the isolation region, the feature comprises a height equal to or greater than a height of the transistors, wherein the interface between the first and second stress layers is disposed on the third gate.

16. The method of claim 13 wherein the first transistor comprises a nFET and the second transistor comprises a pFET.

17. The method of claim 16 wherein the first stress comprises a tensile stress and the second stress comprises a compressive stress.

18. The method of claim 16 wherein the first stress layer comprises silicon nitride which produces a tensile stress and the second stress layer comprises silicon nitride which produces a compressive stress.

19. The method of claim 16 further comprises forming at least a contact over the interface.

20. A method of fabricating an integrated circuit comprising:
providing a substrate with first and second active regions defined thereon with first and second transistors, the first transistor comprises a first type and the second transistor comprises a second type;
forming a first stress layer on the substrate which covers the first and second transistors, the first stress layer produces a first stress;
patterning the first stress layer to remove portions of the first stress layer over the second active region;
forming a second stress layer on the substrate, the second stress layer produces a second stress;
patterning the second stress layer to remove portions of the second stress layer over the first active region, the patterning creates an overlap of the second stress layer over the first stress layer in a region between the active regions to avoid gaps between the first and second stress layers; and
polishing the substrate to produce an interface between the first and second stress layers having a coplanar upper surface without a gap.
